(19) United States
(12) Patent Application Publication
(10) Pub. No.: US 2025/0392295 A1
(43) Pub. Date: Dec. 25, 2025

(54) Oscillating circuit having temperature compensation mechanism

(71) Applicant: REALTEK SEMICONDUCTOR CORPORATION, HSINCHU (TW)

(72) Inventors: CHING-HSIANG CHANG, Hsinchu (TW); CHIA-LING CHANG, HSINCHU (TW); CHI-CHIANG WANG, HSINCHU (TW)

(21) Appl. No.: 19/240,884

(22) Filed: Jun. 17, 2025

(30) Foreign Application Priority Data
Jun. 19, 2024 (TW) 113122746

(51) Int. Cl. H03K 5/134; H03K 5/00

(52) U.S. Cl. CPC H03K 5/134; H03K 2005/00143; H03K 2005/00156

(57) ABSTRACT

The present disclosure discloses an oscillating circuit having a temperature compensation mechanism. A NAND gate receives an input signal transiting from a low state level to a maintaining high state to initialize an oscillating behavior and a delayed control signal to generate an output oscillating signal. A first inverter having a negative temperature coefficient resistance inverts the output oscillating signal to generate an inverted output oscillating signal to be received and delayed by a RC delay circuit, including an oscillating resistor having a positive temperature coefficient resistance and an oscillating capacitor to generate a delayed and inverted control signal. A second inverter inverts the delayed and inverted control signal to generate a delayed control signal. A third inverter inverts the output oscillating signal to generate a final oscillating signal. The negative temperature coefficient resistance and the positive temperature coefficient resistance together determine an oscillating circuit temperature coefficient.

### BACKGROUND OF THE INVENTION

### 1. Field of the Invention

The present disclosure relates to an oscillating circuit having a temperature compensation mechanism.

### 2. Description of Related Art

Electronic oscillator is an electric circuit used to generate a periodic signal and is widely used in the field of such as, but not limited to wireless communication. However, the resistances of the internal elements of the oscillator vary due to the variation of the temperature. Such variation affects the characteristic of electric signals generated thereby.

For example, the oscillating frequency of the electric signals may vary due to the variation of the resistance. If no appropriate temperature compensation mechanism is presented, the oscillator cannot maintain a stable output result of the oscillating frequency due to the variation of the temperature.

### SUMMARY OF THE INVENTION

In consideration of the problem of the prior art, an object of the present disclosure is to provide an oscillating circuit having a temperature compensation mechanism.

The present invention discloses an oscillating circuit having a temperature compensation mechanism that includes a NAND gate, a first inverter, a RC delay circuit, a second inverter and a third inverter. The NAND gate is configured to receive an input signal and a delayed control signal to generate an output oscillating signal, wherein the input signal transits from a low state level to a maintaining high state to initialize an oscillating behavior. The first inverter is configured to receive and invert the output oscillating signal to generate an inverted output oscillating signal to a first terminal, wherein each of a plurality of first internal elements included by the first inverter has a negative temperature coefficient resistive characteristic. The RC delay circuit is configured to receive and delay the inverted output oscillating signal from the first terminal to generate a delayed and inverted control signal at a second terminal. The RC delay circuit includes an oscillating resistor and an oscillating capacitor. The oscillating resistor is electrically coupled between the first terminal and the second terminal, and the oscillating resistor has a positive temperature coefficient resistive characteristic. The oscillating capacitor electrically coupled between the second terminal and a ground terminal. The second inverter is configured to receive and invert the delayed and inverted control signal to generate the delayed control signal. The third inverter is configured to receive and invert the output oscillating signal to generate a final output oscillating signal. The negative temperature coefficient resistive characteristic of the first internal elements and the positive temperature coefficient resistive characteristic of the oscillating resistor together determine a total circuit temperature coefficient characteristic.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1A illustrates a circuit diagram of an oscillating circuit having a temperature compensation mechanism according to an embodiment of the present invention.

FIG. 1B illustrates a circuit diagram of the oscillating circuit under a first operation condition according to an embodiment of the present invention.

FIG. 1C illustrates a circuit diagram of the oscillating circuit under a second operation condition according to an embodiment of the present invention.

FIG. 2A and FIG. 2B illustrate detailed circuit diagrams of the first inverter and the RC delay circuit in FIG. 1 according to an embodiment of the present invention.

FIG. 3 illustrates a circuit diagram of an oscillating circuit having a temperature compensation mechanism according to another embodiment of the present invention.

FIG. 4A and FIG. 4B illustrate detailed circuit diagrams of the second inverter and the compensation capacitor in FIG. 3 according to an embodiment of the present invention.

FIG. 5 illustrates a circuit diagram of an oscillating circuit having a temperature compensation mechanism according to yet another embodiment of the present invention.

### DETAILED DESCRIPTION OF THE PREFERRED EMBODIMENTS

An aspect of the present invention is to provide an oscillating circuit having a temperature compensation mechanism to dispose first internal elements of a first inverter having a negative temperature coefficient and an oscillating resistor of a RC delay circuit having a positive temperature coefficient to accomplish the temperature compensation mechanism, so as to prevent an output oscillating signal outputted by the oscillating circuit from variation due to the effect of the variation of the temperature.

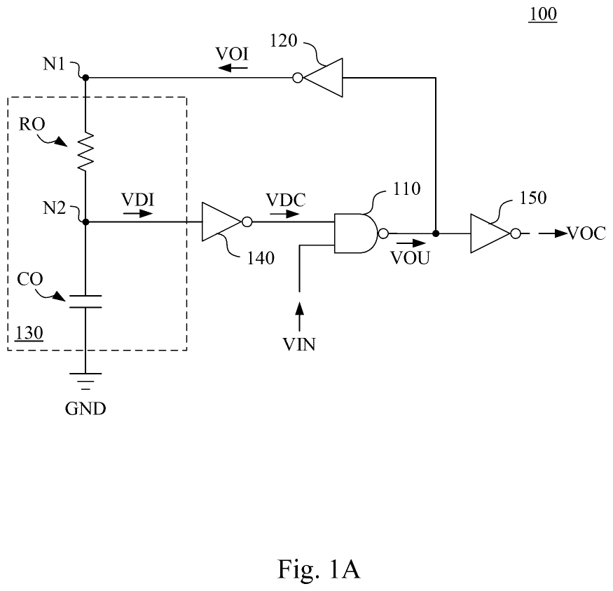

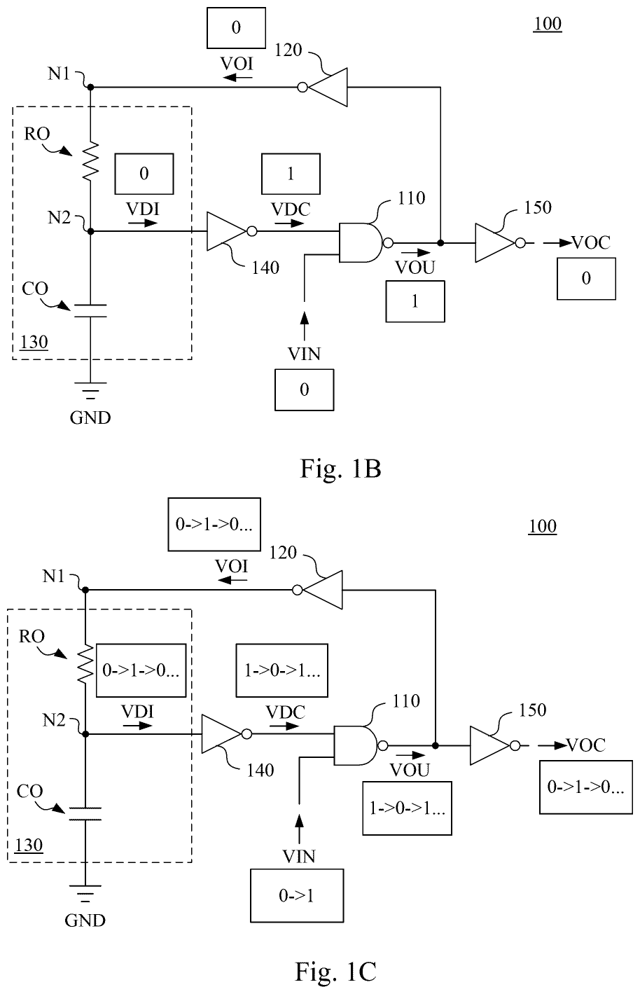

Reference is now made to FIG. 1A. FIG. 1A illustrates a circuit diagram of an oscillating circuit 100 having a temperature compensation mechanism according to an embodiment of the present invention. The oscillating circuit 100 includes a NAND gate 110, a first inverter 120, a RC delay circuit 130, a second inverter 140 and a third inverter 150.

The NAND gate 110 is configured to receive an input signal VIN and a delayed control signal VDC to generate an output oscillating signal VOU. More specifically, the NAND gate 110 performs NAND logic operation on the input signal VIN and the delayed control signal VDC to generate the output oscillating signal VOU.

The first inverter 120 is configured to receive and invert the output oscillating signal VOU to generate an inverted output oscillating signal VOI to a first terminal N1.

The RC delay circuit 130 is configured to receive the inverted output oscillating signal VOI from the first terminal N1 and generate a delayed and inverted control signal VDI at a second terminal N2. In an embodiment, the RC delay circuit 130 includes an oscillating resistor RO and an oscillating capacitor CO. The oscillating resistor RO is electrically coupled between the first terminal N1 and the second terminal N2. The oscillating capacitor CO is electrically coupled between the second terminal N2 and a ground terminal GND.

The second inverter 140 is configured to receive and invert the delayed and inverted control signal VDI from the second terminal N2 to generate the delayed control signal VDC.

The third inverter 150 is configured to receive and invert the output oscillating signal VOU to generate a final output oscillating signal VOC. In an embodiment, the final output oscillating signal VOC can be further outputted to an external circuit (not illustrated in the figure) such that the external circuit operates accordingly.

The oscillating circuit 100 operates according to a voltage level of the input signal VIN. Different operation conditions of the oscillating circuit 100 that occur depending on the different levels of the input signal VIN are described in the following paragraphs.

Reference is now made to FIG. 1B. FIG. 1B illustrates a circuit diagram of the oscillating circuit 100 under a first operation condition according to an embodiment of the present invention.

Under the first operation condition of the oscillating circuit 100, the input signal VIN is at a low state level (0) to deactivate the oscillating behavior of the oscillating circuit 100. In FIG. 1B, either 0 or 1 in a frame is labeled to indicate the voltage level of each of the signals in the oscillating circuit 100 under the first operation condition.

After receiving the input signal VIN at the low state level (0), the NAND gate 110 generates the output oscillating signal VOU at a high state level (1) based on the NAND logic operation no matter what the voltage level of the delayed control signal VDC is.

The first inverter 120 receives and inverts the output oscillating signal VOU at the high state level (1) to generate the inverted output oscillating signal VOI at the low state level (0) to the first terminal N1.

According to the inverted output oscillating signal VOI at the low state level (0), the RC delay circuit 130 generates the delayed and inverted control signal VDI at the low state level (0) at the second terminal N2. The second inverter 140 receives and inverts the delayed and inverted control signal VDI at the low state level (0) from the second terminal N2 to generate the delayed control signal VDC at the high state level (1).

The third inverter 150 receives and inverts the output oscillating signal VOU at the high state level (1) to generate the final output oscillating signal VOC at the low state level (0).

As a result, under the condition that the input signal VIN stays at the low state level (0), the final output oscillating signal VOC also stays at the low state level (0). The oscillating circuit 100 does not have the oscillating behavior.

Reference is now made to FIG. 1C. FIG. 1C illustrates a circuit diagram of the oscillating circuit 100 under a second operation condition according to an embodiment of the present invention.

Under the second operation condition of the oscillating circuit 100, the input signal VIN switches from the low state level (0) to a maintaining high state level (1) to activate the oscillating behavior of the oscillating circuit 100. In FIG. 1C, either 0 or 1 in a frame is labeled to indicate the voltage level of each of the signals in the oscillating circuit 100 under the second operation condition, wherein an arrow “>” is used to express the process of the switching of each of the voltage levels between different operation stages.

In an initial stage of the second operation condition, the input signal VIN is still at the low state level (0) such that the voltage levels of the signals of the oscillating circuit 100 are the same as those in FIG. 1B.

In the first stage, the input signal VIN switches to the high state level (1) and is maintained at the high state level (1). After receiving the input signal VIN at the high state level, the NAND gate 110 performs NAND logic operation on the input signal VIN and the delayed control signal VDC that is still at the high state level (1) in the first operation condition to generate the output oscillating signal VOU at the low state level (0). The first inverter 120 receives and inverts the output oscillating signal VOU at the low state level (0) to generate the inverted output oscillating signal VOI at the high state level (1) to the first terminal N1.

The RC delay circuit 130 is charged by the inverted output oscillating signal VOI at the high state level (1) and generates the delayed and inverted control signal VDI at the high state level (1) at the second terminal N2. The second inverter 140 receives and inverts the delayed and inverted control signal VDI at the high state level (1) from the second terminal N2 to generate the delayed control signal VDC at the low state level (0).

The third inverter 150 receives and inverts the output oscillating signal VOU at the low state level (0) to generate the final output oscillating signal VOC at the high state level (1).

In the second stage, after receiving the delayed control signal VDC at the low state level (0), the NAND gate 110 performs the NAND logic operation to generate the output oscillating signal VOU at the high state level (1). The first inverter 120 receives and inverts the output oscillating signal VOU at the high state level (1) to generate the inverted output oscillating signal VOI at the low state level (0) to the first terminal N1.

The RC delay circuit 130 is charged by the inverted output oscillating signal VOI at the low state level (0) to generate the delayed and inverted control signal VDI at the low state level (0) at the second terminal N2. The second inverter 140 receives and inverts the delayed and inverted control signal VDI at the low state level (0) from the second terminal N2 to generate the delayed control signal VDC at the high state level (1).

The third inverter 150 receives and inverts the output oscillating signal VOU at the high state level (1) to generate the final output oscillating signal VOC at the low state level (0).

As a result, under the condition that the input signal VIN maintains at the high state level (1), the oscillating circuit 100 keeps operating in the first stage and the second stage in turn to generate the oscillating behavior.

In the operation of the circuits described above, an oscillating time period of the oscillating circuit 100 is determined by circuit parameters related to the charging and discharging of the RC delay circuit 130. More specifically, the oscillating time period of the oscillating circuit 100 is determined not only by the circuit parameters of the RC delay circuit 130 itself, but also by the circuit parameters of a plurality of first internal elements (not illustrated in FIG. 1) included by the first inverter 120 that charges and discharges the RC delay circuit 130.

In an embodiment, the plurality of first internal elements included by the first inverter 120 have a negative temperature coefficient resistive characteristic. The oscillating resistor RO included by the RC delay circuit 130 has a positive temperature coefficient resistive characteristic. The negative temperature coefficient resistive characteristic of the first internal elements and the positive temperature coefficient resistive characteristic of the oscillating resistor RO described above together determine the total circuit temperature coefficient characteristic.

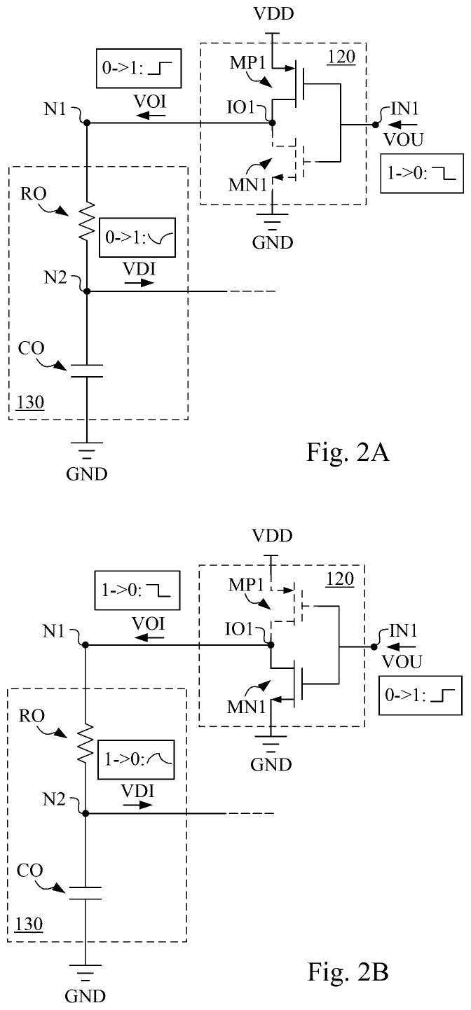

Reference is now made to FIG. 2A and FIG. 2B at the same time. FIG. 2A and FIG. 2B illustrate detailed circuit diagrams of the first inverter 120 and the RC delay circuit 130 in FIG. 1 according to an embodiment of the present invention.

In an embodiment, the first internal elements included by the first inverter 120 include a first P-type transistor MP1 and a first N-type transistor MN1.

The first P-type transistor MP1 is electrically coupled between a supply voltage V_{DD} and the first inverter output terminal IO1. The first N-type transistor MN1 is electrically coupled between the first inverter output terminal IO1 and the ground terminal GND.

The first P-type transistor MP1 and the first N-type transistor MN1 receive the output oscillating signal VOU through a first inverter input terminal IN1 and are controlled thereby so as to generate the inverted output oscillating signal VOI at a first inverter output terminal IO1 to the first terminal N1. The oscillating resistor RO of the RC delay circuit 130 receives the inverted output oscillating signal VOI from the first terminal N1.

In FIG. 2A and FIG. 2B, the voltage levels and waveforms of the voltage transition of the signals are labeled to describe the operation of the first P-type transistor MP1 and the first N-type transistor MN1.

In FIG. 2A, the oscillating circuit 100 switches from the second stage to the first stage in the second operation condition. The first P-type transistor MP1 and the first N-type transistor MN1 of the first inverter 120 receives the output oscillating signal VOU switching from the high state level to the low state level (1->0) from the first inverter input terminal IN1 and are controlled thereby.

Under such a condition, the first P-type transistor MP1 is turned on and the first N-type transistor MN1 is turned off. In FIG. 2A, the first P-type transistor MP1 that is turned on is illustrated by solid lines and the first N-type transistor MN1 that is turned off is illustrated by dashed lines. The first P-type transistor MP1 that is turned on charges the RC delay circuit 130 to generate the inverted output oscillating signal VOI switching from the low state level to the high state level (0->1). The RC delay circuit 130 generates the delayed and inverted control signal VDI gradually switching from the low state level to the high state level (0->1) at the second terminal N2.

In FIG. 2B, the oscillating circuit 100 switches from the first stage to the second stage in the second operation condition. The first P-type transistor MP1 and the first N-type transistor MN1 of the first inverter 120 receives the output oscillating signal VOU switching from the low state level to the high state level (0->1) from the first inverter input terminal IN1 and are controlled thereby.

Under such a condition, the first P-type transistor MP1 is turned off and the first N-type transistor MN1 is turned on. In FIG. 2B, the first P-type transistor MP1 that is turned off is illustrated by dashed lines and the first N-type transistor MN1 that is turned on is illustrated by solid lines. The first N-type transistor MP1 that is turned on discharge the RC delay circuit 130 to generate the inverted output oscillating signal VOI switching from the high state level to the low state level (1->0). The RC delay circuit 130 generates the delayed and inverted control signal VDI gradually switching from the high state level to the low state level (1->0) at the second terminal N2.

In the process described above, each of the first P-type transistor MP1 and the first N-type transistor MN1 has an on-resistance when being turned on.

In an embodiment, a current charged voltage level of the delayed and inverted control signal VDI is V₀, a target charged voltage level of the delayed and inverted control signal VDI is V_{E}, an on-resistance of each of the first P-type transistor MP1 and the first N-type transistor MN1 is R_{ON1}, an oscillating resistance of the oscillating resistor RO is R_{ES}, an oscillating capacitance of the oscillating capacitor CO is C_{O} and a charging time of the delayed and inverted control signal VDI is t.

Under such a condition, the time constant of the RC delay circuit 130 and the first inverter 120 operating together is τ=(R_{ON1}+R_{ES})×C_{O}. The charging behavior of the delayed and inverted control signal VDI can be expressed by the following equation:

$${V}_{0} = {V}_{E} \times ( 1 - e ( - t / τ ) ) \qquad ( equation 1 )$$

In (equation 1), e is the base number of the natural logarithmic function. When the on-resistances of the first P-type transistor MP1 and the first N-type transistor MN1 equal to each other, the charging period T of the RC delay circuit 130 is two times of the charging time t according to the calculation of (equation 1) and can be expressed by the following equation:

$$T = 2 \times t = 2 ( {R}_{ON 1} + {R}_{ES} ) \times {C}_{O} \times ln ( {V}_{E} / ( {V}_{E} - {V}_{0} ) ) \qquad ( equation 2 )$$

In an embodiment, the on-resistance of each of the first P-type transistor MP1 and the first N-type transistor MN1 has the negative temperature coefficient resistive characteristic. Since the oscillating resistor RO included by the RC delay circuit 130 has the positive temperature coefficient resistive characteristic, the total circuit temperature coefficient characteristic is determined together by the negative temperature coefficient resistive characteristic of the first internal elements (i.e., the on-resistances of the first P-type transistor MP1 and the first N-type transistor MN1) and the positive temperature coefficient resistive characteristic of the oscillating resistor RO.

More specifically, the effect on the charging and discharging behaviors of the RC delay circuit 130 due to the temperature variation originated by the negative temperature coefficient resistive characteristic of the on-resistances can be compensated by the positive temperature coefficient resistive characteristic of the oscillating resistor RO.

Under the appropriate conduction condition of the first P-type transistor MP1 and the first N-type transistor MN1 and the appropriate material choice of the oscillating resistor RO, the total circuit temperature coefficient characteristic controls the delayed and inverted control signal VDI to have a zero temperature coefficient such that the final output oscillating signal VOC generated by the oscillating circuit 100 has the zero temperature coefficient. It is appreciated that the term “have the zero temperature coefficient” means that the characteristic of the signals, such as but not limited to the oscillating frequency is not varied due to the variation of the temperature.

The (equation 2) described above is described under the condition that the on-resistances of the first P-type transistor MP1 and the first N-type transistor MN1 equal to each other. In practical implementation, the on-resistances of the first P-type transistor MP1 and the first N-type transistor MN1 may be different such that the charging time (related to the on-resistance of the first P-type transistor MP1) and the discharging time (related to the on-resistance of the first N-type transistor MN1) are required to be calculated separately so as to be added to obtain the charging period T of the RC delay circuit 130. The detail is not further described herein.

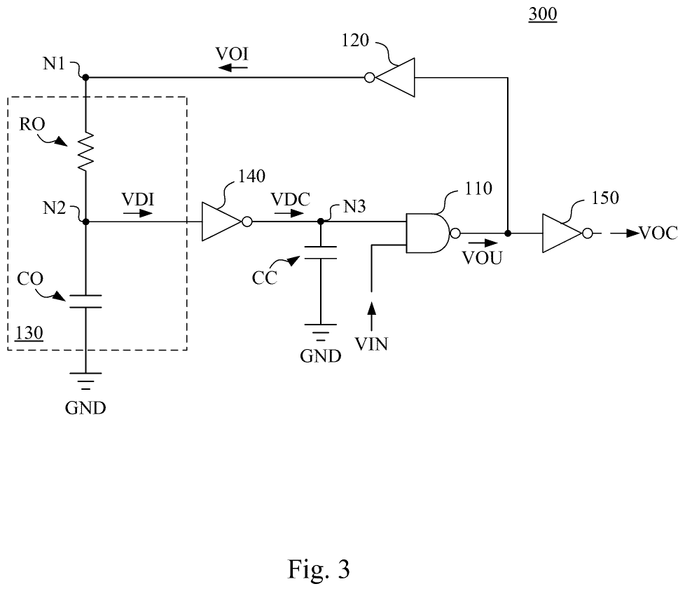

Reference is now made to FIG. 3. FIG. 3 illustrates a circuit diagram of an oscillating circuit 300 having a temperature compensation mechanism according to another embodiment of the present invention. Similar to the oscillating circuit 100 in FIG. 1, the oscillating circuit 300 in FIG. 3 includes the NAND gate 110, the first inverter 120, the RC delay circuit 130, the second inverter 140 and the third inverter 150. The identical elements and operation are not described herein.

In the present embodiment, the oscillating circuit 300 further includes a compensation capacitor CC. The compensation capacitor CC is electrically coupled to a third terminal N3 that electrically couples the second inverter 140 and the NAND gate 110 to transmit the delayed control signal VDC and the ground terminal GND.

A plurality of the second internal elements (not illustrated in FIG. 3) included by the second inverter 140 have the negative temperature coefficient resistive characteristic to oscillate with the compensation capacitor CC. Under such a condition, the negative temperature coefficient resistive characteristic of first internal elements of the first inverter 120 and the second internal elements of the second inverter 14 and the positive temperature coefficient resistive characteristic of the oscillating resistor RO together determine the total circuit temperature coefficient characteristic.

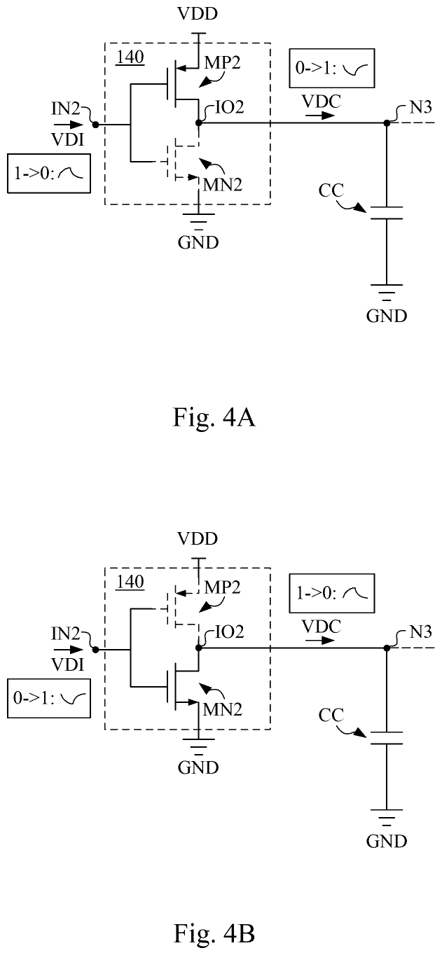

Reference is now made to FIG. 4A and FIG. 4B at the same time. FIG. 4A and FIG. 4B illustrate detailed circuit diagrams of the second inverter 140 and the compensation capacitor CC in FIG. 3 according to an embodiment of the present invention.

In an embodiment, the second internal elements included by the second inverter 140 include a second P-type transistor MP2 and a second N-type transistor MN2.

The second P-type transistor MP2 is electrically coupled between the supply voltage V_{DD} and a second inverter output terminal IO2. The second N-type transistor MN2 is electrically coupled between the second inverter output terminal IO2 and the ground terminal GND.

The second P-type transistor MP2 and the second N-type transistor MN2 receive the delayed and inverted control signal VDI from a second inverter input terminal IN2 and are controlled thereby to generate the delayed control signal VDC at the second inverter output terminal IO2 to the third terminal N3. The NAND gate 110 receives the delayed control signal VDC from the third terminal N3.

In FIG. 4A and FIG. 4B, the voltage levels and waveforms of the voltage transition of the signals are labeled to describe the operation of the second P-type transistor MP2 and the second N-type transistor MN2.

In FIG. 4A, the oscillating circuit 100 switches from the second stage to the first stage in the second operation condition. The second P-type transistor MP2 and the second N-type transistor MN2 of the second inverter 140 receive the delayed and inverted control signal VDI switching from the high state level to the low state level (1->0) from the second inverter input terminal IN2 and are controlled thereby.

Under such a condition, the second P-type transistor MP2 is turned on and the second N-type transistor MN2 is turned off. In FIG. 4A, the second P-type transistor MP2 that is turned on is illustrated by solid lines and the second N-type transistor MN2 that is turned off is illustrated by dashed lines. The second P-type transistor MP2 that is turned on charges the compensation capacitor CC such that the delayed control signal VDC gradually switching from the low state level to the high state level (0->1) is generated at the third terminal N3.

In FIG. 4B, the oscillating circuit 100 switches from the first stage to the second stage in the second operation condition. The second P-type transistor MP2 and the second N-type transistor MN2 of the second inverter 140 receive the delayed and inverted control signal VDI switching from the low state level to the high state level (0->1) and are controlled thereby.

Under such a condition, the second P-type transistor MP2 is turned off and the second N-type transistor MN2 is turned on. In FIG. 4B, the second P-type transistor MP2 that is turned off is illustrated by dashed lines and the second N-type transistor MN2 that is turned on is illustrated by solid lines. The second N-type transistor MN2 that is turned on discharge the compensation capacitor CC such that the delayed control signal VDC gradually switching from the high state level to the low state level (1->0) is generated at the third terminal N3.

In the process described above, each of the second P-type transistor MP2 and the second N-type transistor MN2 has an on-resistance when being turned on.

In an embodiment, the current charged voltage level of the delayed and inverted control signal VDI is V₀, the target charged voltage level of the delayed and inverted control signal VDI is V_{E}, the on-resistance of each of the first P-type transistor MP1 and the first N-type transistor MN1 is R_{ON1}, the on-resistance of the second P-type transistor MP2 and the second N-type transistor MN is R_{ON2}, the oscillating resistance of the oscillating resistor RO is R_{ES}, the oscillating capacitance of the oscillating capacitor CO is C_{O}, the compensation capacitance of the compensation capacitor CC is C_{C} and the charging time of the delayed and inverted control signal VDI is t.

Under such a condition, the time constant of the second inverter 140 and the compensation capacitor CC operating together is R_{ON2}×C_{C}. The charging period T of the RC delay circuit 130 is two times of the charging time t and can be expressed by the following equation:

$$T = 2 \times t = 2 ( {R}_{ON 1} + {R}_{ES} ) \times {C}_{O} \times ln ( {V}_{E} / ( {V}_{E} - {V}_{0} ) ) + 2 {R}_{ON 2} \times {C}_{C} \times ( {V}_{D D} / ( {V}_{DD} - {V}_{0} ) ) \qquad ( equation 3 )$$

In an embodiment, the on-resistance of each of the second P-type transistor MP2 and the second N-type transistor MN2 has the negative temperature coefficient resistive characteristic. When the positive temperature coefficient resistive characteristic of the oscillating resistor RO included by the RC delay circuit 130 is stronger than the negative temperature coefficient resistive characteristic of the on-resistances of the first P-type transistor MP1 and the first N-type transistor MN1 (e.g., the positive temperature coefficient is larger than the negative temperature coefficient), the second inverter 140 provides the negative temperature coefficient resistive characteristic to perform compensation based on the disposition of the compensation capacitor CC. The total circuit temperature coefficient characteristic is determined together by the negative temperature coefficient resistive characteristic of the first internal elements (i.e., the on-resistances of the first P-type transistor MP1 and the first N-type transistor MN1) and the second internal elements (i.e., the on-resistances of the second P-type transistor MP2 and the second N-type transistor MN2 [symbol] on-resistance) and the positive temperature coefficient resistive characteristic of the oscillating resistor RO.

In an embodiment, under the appropriate conduction condition of the first P-type transistor MP1, the first N-type transistor MN1, the second P-type transistor MP2 and the second N-type transistor MN2 and the appropriate material choice of the oscillating resistor, the total circuit temperature coefficient characteristic controls the delayed and inverted control signal VDI to have a zero temperature coefficient such that the final output oscillating signal VOC generated by the oscillating circuit 100 has the zero temperature coefficient.

The (equation 3) described above is described under the condition that the on-resistances of the first P-type transistor MP1 and the first N-type transistor MN1 equal to each other and the on-resistances of the second P-type transistor MP2 and the second N-type transistor MN2 equal to each other. In practical implementation, the on-resistances of the first P-type transistor MP1 and the first N-type transistor MN1 may be different, and the on-resistances of the second P-type transistor MP2 and the second N-type transistor MN2 may also be different such that the charging time and the discharging time are required to be calculated separately so as to be added to obtain the charging period T of the RC delay circuit 130. The detail is not further described herein.

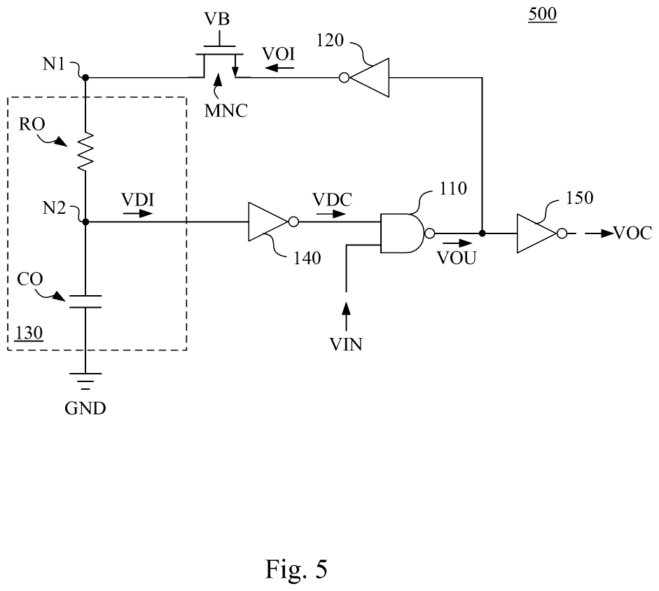

Reference is now made to FIG. 5. FIG. 5 illustrates a circuit diagram of an oscillating circuit 500 having a temperature compensation mechanism according to yet another embodiment of the present invention. Similar to the oscillating circuit 100 in FIG. 1, the oscillating circuit 500 in FIG. 5 includes the NAND gate 110, the first inverter 120, the RC delay circuit 130, the second inverter 140 and the third inverter 150. The identical elements and operation are not described herein.

In the present embodiment, the oscillating circuit 500 further includes a compensation transistor MNC. The compensation transistor MNC is electrically coupled between the first inverter 120 and the first terminal N1 and is controlled by a biased voltage VB to be kept being turned on.

The compensation transistor MNC that is turned on has a compensation on-resistance and the compensation on-resistance has a negative temperature coefficient resistive characteristic. When the first inverter 120 charges and discharges the RC delay circuit 130, the equivalent resistor of the on-resistance of the compensation on-resistance is coupled in series with the equivalent resistor of the on-resistance of the first internal elements of the first inverter 120 and the oscillating resistor RO included by the RC delay circuit 130. As a result, when the compensation on-resistance is R_{ON3}, (equation 2) is modified to be:

$$T = 2 \times t = 2 ( {R}_{ON 1} + {R}_{ES} + {R}_{ON 3} ) \times {C}_{O} \times ln ( {V}_{E} / ( {V}_{E} - {V}_{0} ) ) \qquad ( equation 4 )$$

In an embodiment, when the positive temperature coefficient resistive characteristic of the oscillating resistor RO included by the RC delay circuit 130 is stronger than the negative temperature coefficient resistive characteristic of the on-resistances of the first P-type transistor MP1 and the first N-type transistor MN1, the first inverter 120 can be compensated according to the negative temperature coefficient resistive characteristic provided based on the disposition of the compensation transistor MNC. The total circuit temperature coefficient characteristic is determined together by the negative temperature coefficient resistive characteristic of the first internal elements (i.e., the on-resistances of the first P-type transistor MP1 and the first N-type transistor MN1) and the compensation transistor MNC and the positive temperature coefficient resistive characteristic of the oscillating resistor RO.

In an embodiment, Under the appropriate conduction condition of the first P-type transistor MP1, the first N-type transistor MN1 and the compensation transistor MNC and the appropriate material choice of the oscillating resistor RO, the total circuit temperature coefficient characteristic controls the delayed and inverted control signal VDI to have a zero temperature coefficient such that the final output oscillating signal VOC generated by the oscillating circuit 100 has the zero temperature coefficient.

It is appreciated that in FIG. 5, the compensation transistor MNC illustrated to be an N-type transistor. In other embodiments, the compensation transistor MNC can also be implemented by a P-type transistor. The present invention is not limited thereto.

In an embodiment, the oscillating circuit 100 in FIG. 1 may simultaneously include the compensation capacitor CC in FIG. 3 and the compensation transistor MNC in FIG. 5. Under such a condition, the total circuit temperature coefficient characteristic is determined together by the negative temperature coefficient resistive characteristic of the first internal elements (i.e., the on-resistances of the first P-type transistor MP1 and the first N-type transistor MN1), the second internal elements (i.e., the on-resistances of the second P-type transistor MP2 and the second N-type transistor MN2 [symbol] on-resistance) and the compensation transistor MNC and the positive temperature coefficient resistive characteristic of the oscillating resistor RO. Under the appropriate conduction condition of the first P-type transistor MP1, the first N-type transistor MN1, the second P-type transistor MP2, the second N-type transistor MN2 and the compensation transistor MNC and the appropriate material choice of the oscillating resistor, the total circuit temperature coefficient characteristic controls the delayed and inverted control signal VDI to have a zero temperature coefficient such that the final output oscillating signal VOC generated by the oscillating circuit 100 has the zero temperature coefficient.

It is appreciated that the embodiments described above are merely an example. In other embodiments, it is appreciated that many modifications and changes may be made by those of ordinary skill in the art without departing, from the spirit of the invention.

In summary, the oscillating circuit having the temperature compensation mechanism disposes first internal elements of a first inverter having a negative temperature coefficient and an oscillating resistor of a RC delay circuit having a positive temperature coefficient to accomplish the temperature compensation mechanism, so as to prevent an output oscillating signal outputted by the oscillating circuit from variation due to the effect of the variation of the temperature.

The aforementioned descriptions represent merely the preferred embodiments of the present disclosure, without any intention to limit the scope of the present disclosure thereto. Various equivalent changes, alterations, or modifications based on the claims of present disclosure are all consequently viewed as being embraced by the scope of the present disclosure.

What is claimed is:

1. An oscillating circuit having a temperature compensation mechanism, comprising:
a NAND gate configured to receive an input signal and a delayed control signal to generate an output oscillating signal, wherein the input signal transits from a low state level to a maintaining high state to initialize an oscillating behavior;
a first inverter configured to receive and invert the output oscillating signal to generate an inverted output oscillating signal to a first terminal, wherein each of a plurality of first internal elements comprised by the first inverter has a negative temperature coefficient resistive characteristic;
a RC delay circuit configured to receive and delay the inverted output oscillating signal from the first terminal to generate a delayed and inverted control signal at a second terminal, the RC delay circuit comprising:
an oscillating resistor electrically coupled between the first terminal and the second terminal, and the oscillating resistor has a positive temperature coefficient resistive characteristic; and
an oscillating capacitor electrically coupled between the second terminal and a ground terminal;
a second inverter configured to receive and invert the delayed and inverted control signal to generate the delayed control signal; and
a third inverter configured to receive and invert the output oscillating signal to generate a final output oscillating signal;
wherein the negative temperature coefficient resistive characteristic of the first internal elements and the positive temperature coefficient resistive characteristic of the oscillating resistor together determine a total circuit temperature coefficient characteristic.

2. The oscillating circuit of claim 1, wherein the first internal elements comprise:
a first P-type transistor electrically coupled between a supply voltage and a first inverter output terminal; and
a first N-type transistor electrically coupled between the first inverter output terminal and the ground terminal;
wherein the first P-type transistor and the first N-type transistor receives the output oscillating signal through a first inverter input terminal and are controlled thereby so as to generate the inverted output oscillating signal at the first inverter output terminal to the first terminal; and
each of the first P-type transistor and the first N-type transistor has an on-resistance when being turned on, and the on-resistance has the negative temperature coefficient resistive characteristic.

3. The oscillating circuit of claim 2, wherein a current charged voltage level of the delayed and inverted control signal is V₀, a target charged voltage level of the delayed and inverted control signal is V_{E}, the on-resistance of the first internal elements is R_{ON1}, an oscillating resistance of the oscillating resistor is R_{ES}, an oscillating capacitance of the oscillating capacitor is C_{O}, a charging time of the delayed and inverted control signal is t;
a time constant of the RC delay circuit and the first inverter operating together is (R_{ON1}+R_{ES})×C_{O}; and
an oscillating time period of the RC delay circuit and the first inverter operating together is T and T=2×t=2 (R_{ON1}+R_{ES})×C_{O}×ln(V_{E}/(V_{E}−V₀)).

4. The oscillating circuit of claim 1, further comprising a compensation capacitor electrically coupled to a third terminal that electrically couples the second inverter and the NAND gate to transmit the delayed control signal and the ground terminal;
wherein a plurality of second internal elements comprised by the second inverter comprises have the negative temperature coefficient resistive characteristic so as to oscillate with the compensation capacitor; and
the negative temperature coefficient resistive characteristic of the first internal elements and the second internal elements and the positive temperature coefficient resistive characteristic of the oscillating resistor together determine the total circuit temperature coefficient characteristic.

5. The oscillating circuit of claim 4, wherein the second internal elements comprise:
a second P-type transistor electrically coupled between a supply voltage and a second inverter output terminal; and
a second N-type transistor electrically coupled between the second inverter output terminal and the ground terminal;
wherein the second P-type transistor and the second N-type transistor receive the delayed and inverted control signal through a second inverter input terminal and are controlled thereby so as to generate the delayed control signal at the second inverter output terminal; and
wherein each of the second P-type transistor and the second N-type transistor has an on-resistance when being turned on, and the on-resistance has the negative temperature coefficient resistive characteristic.

6. The oscillating circuit of claim 5, wherein a current charged voltage level of the delayed and inverted control signal is V₀, a target charged voltage level of the delayed and inverted control signal is V_{E}, a the supply voltage Value of the supply voltage is V_{DD}, the on-resistance of the first internal elements is R_{ON1}, the on-resistance of the second internal elements is R_{ON2}, an oscillating resistance of the oscillating resistor is R_{ES}, an oscillating capacitance of the oscillating capacitor is C_{O}, a compensation capacitance of the compensation capacitor is C_{C}, a charging time of the delayed and inverted control signal is t;
a time constant of the RC delay circuit and the first inverter operating together is (R_{ON1}+R_{ES})×C_{O}, a time constant of the second inverter and the compensation capacitor is R_{ON2}×C_{C}; and
an oscillating time period of the RC delay circuit, the first inverter and the second inverter operating together is T and T=2×t=2 (R_{ON1}+R_{ES})×C_{O}×ln(V_{E}/(V_{E}−V₀))+2R_{ON2}×C_{C}×(V_{DD}/(V_{DD}−V₀)).

7. The oscillating circuit of claim 1, further comprising a compensation transistor electrically coupled between the first inverter and the first terminal and controlled by a biased voltage to be kept being turned on;
the compensation transistor that is turned on has a compensation on-resistance and the compensation on-resistance has the negative temperature coefficient resistive characteristic; and
the negative temperature coefficient resistive characteristic of the first internal elements and the compensation transistor and the positive temperature coefficient resistive characteristic of the oscillating resistor together determine the total circuit temperature coefficient characteristic.

8. The oscillating circuit of claim 7, wherein a current charged voltage level of the delayed and inverted control signal is V₀, a target charged voltage level of the delayed and inverted control signal is V_{E}, the on-resistance of the first internal elements is R_{ON1}, a oscillating resistance of the oscillating resistor is R_{ES}, a compensation on-resistance of the compensation on-resistance is R_{ON3}, an oscillating capacitance of the oscillating capacitor is C_{O}, a charging time of the delayed and inverted control signal is t;
a time constant of the RC delay circuit and the first inverter operating together is (R_{ON1}+R_{ES}+R_{ON3})×C_{O}; and
an oscillating time period of the RC delay circuit and the first inverter operating together is T and T=2×t=2 (R_{ON1}+R_{ES}+R_{ON3})×C_{O}×ln (V_{E}/(V_{E}−V₀)).

9. The oscillating circuit of claim 1, further comprising a compensation capacitor and a compensation transistor, the compensation capacitor being electrically coupled between a third terminal of the second inverter configured to generate the delayed control signal and the ground terminal, and the compensation transistor being electrically coupled between the first terminal and the oscillating resistor and being controlled by a biased voltage to be kept being turned on;
wherein a plurality of second internal elements comprised by the second inverter have the negative temperature coefficient resistive characteristic to oscillate with the compensation capacitor;
the compensation transistor that is turned on has a compensation on-resistance and the compensation on-resistance has the negative temperature coefficient resistive characteristic; and
the negative temperature coefficient resistive characteristic of the first internal elements, the second internal elements and the positive temperature coefficient resistive characteristic of the compensation transistor together determine the total circuit temperature coefficient characteristic.

10. The oscillating circuit of claim 1, wherein the total circuit temperature coefficient characteristic controls the final output oscillating signal to have a zero temperature coefficient.
